(19) United States
(12) Patent Application Publication
(10) Pub. No.: US 2008/0196666 A1
(43) Pub. Date: Aug. 21, 2008

(54) Shower head and cvd apparatus using the same

(75) Inventor: Masato Toshima, Saratoga, CA (US)

Correspondence Address: BIRCH STEWART KOLASCH & BIRCH, PO BOX 747, FALLS CHURCH, VA, 22040-0747, US

(73) Assignees: Masato Toshima, Saratoga, CA (US); Kam S. Law, San Jose, CA (US)

(21) Appl. No.: 11/826,336

(22) Filed: Jul. 13, 2007

(30) Foreign Application Priority Data
Feb. 20, 2007 (JP) 2007-39923

(51) Int. Cl. C23C 16/00; C23C 16/34

(52) U.S. Cl. 118/723 E; 118/715

(57) ABSTRACT

The showerhead for a CVD apparatus can be easily produced and is capable of forming a film efficiently. The showerhead comprises: a shower plate being made of a metal; and a porous plate contacting a rear face of the shower plate. A plurality of gas diffusion holes are formed in a plate section of the shower plate, which faces a workpiece, and penetrate the plate section in the thickness direction, and the porous plate covers all of the gas diffusion holes.

### BACKGROUND OF THE INVENTION

The present invention relates to a showerhead and a CVD (Chemical Vapor Deposition) apparatus using the showerhead.

In a typical plasma CVD apparatus, a process gas for forming a film is supplied into a chamber, and then RF (Radio Frequency) waves are applied to a showerhead so as to generate plasma and ionize the gas, so that the film is formed on a surface of a workpiece, which is disposed to face the shower head.

The showerhead of the CVD apparatus is used for efficiently ionizing the gas and uniformly forming the film on the surface of the workpiece. Various of types of showerheads have been provided. A typical showerhead has a plate section, which faces the workpiece and in which gas diffusion holes are formed, and the gas is sprayed from the gas diffusion holes toward the workpiece, so that the gas is dissociated and the film is formed thereon. Further, Japanese Patent Gazettes No. 2003-28142 and No. 2003-7682 disclose showerheads, whose plate sections are made of a porous ceramic; and Japanese Patent Gazette No. 2005-516407 discloses a showerhead, whose plate section has long grooves in which gas diffusion holes are bored.

In the showerhead having the plate section, a large number (several hundreds to several thousands) of the gas diffusion holes must be formed, so a production cost of the plate section must be increased. Since the gas diffusion holes, whose inner diameters are about 0.2 mm, are manually bored, one by one, by drilling, it takes for a several days to penetrate the gas diffusion holes in one showerhead.

On the other hand, in comparison with the showerhead in which the gas diffusion holes are bored in the plate section, the showerhead made of the porous ceramic is capable of uniformly spraying the gas, and no gas diffusion holes are manually bored so that a production cost can be lowered. However, in the showerhead made of the porous ceramic, the gas cannot be efficiently ionized, so the showerhead is not suitable for forming a film with gas species which are hard to be ionized, e.g., silicon nitride (SiNx).

### SUMMARY OF THE INVENTION

The present invention was conceived to solve the above described problems.

An object of the present invention is to provide a showerhead for a CVD apparatus, in which a plurality of gas diffusion holes are formed in a plate section, can be easily produced and which is capable of efficiently forming a film with gas species which are hard to be ionized, e.g., silicon nitride (SiNx).

Another object is to provide a CVD apparatus using said showerhead.

To achieve the objects, the present invention has following structures.

Namely, the showerhead for a CVD apparatus comprises:
a shower plate being made of a metal; and
a porous plate contacting a rear face of the shower plate,
a plurality of gas diffusion holes are formed in a plate section of the shower plate, which faces a workpiece, and penetrate the plate section in the thickness direction, and
the porous plate covers all of the gas diffusion holes.

In the showerhead, the gas diffusion holes may be elongate holes. With this structure, a gas can be efficiently ionized, so that a film can be efficiently formed. Note that, planar shapes of the elongated holes may be long linear holes and long curved holes.
In the showerhead, a thickness of the porous plate may be thicker in a high gas-density area of a gas introduction space, which is formed on the rear side of the shower head, so that the amount of gas permeation through the gas diffusion holes is uniform across the entire showerhead. Further, density of the porous plate may be higher in a high gas-density area of a gas introduction space, which is formed on the rear side of the shower head, so that the amount of gas permeation through the gas diffusion holes is uniform across the entire showerhead. In these cases, the gas density on the rear side of the showerhead can be made uniform, so that the film can be uniformly formed.
In the showerhead, the porous plate may have a perimeter section, which surrounds a gas diffusion hole area and which is not gas-permeable. With this structure, no gas invades into the gas diffusion holes via the contact part between the porous plate and the shower plate, so that the film can be more suitably formed.
In the showerhead, a metal plate may be installed instead of the porous plate, and the metal plate may have: vertical holes penetrating through the metal plate in the thickness direction; and communicating grooves being formed in a surface of the metal plate, which contacts the plate section of the shower plate, the communicating grooves mutually communicating the gas diffusion holes. With this structure, the gas for forming the film can be uniformly supplied to the gas diffusion holes, so that the film can be formed suitably.

Another showerhead for a CVD apparatus comprises a main body part being made of a metallic porous material, and

a plurality of gas diffusion grooves are formed in a plate section of the main body part, which faces a workpiece.

In the showerhead, the gas diffusion grooves may be elongated grooves in plan view. With this structure, the supplied gas can be efficiently ionized, and film-forming efficiency can be improved.
In the showerhead, a thickness of the main body part may be thicker in a high gas-density area of a gas introduction space, which is formed on the rear side of the shower head, so that the amount of gas permeation through the gas diffusion grooves is uniform across the entire main body part. Further, density of the main body part may be higher in a high gas-density area of a gas introduction space, which is formed on the rear side of the shower head, so that the amount of gas permeation through the gas diffusion grooves is uniform across the entire main body part. With these structures, the film can be uniformly formed on the surface of the workpiece.

Further, the CVD apparatus of the present invention comprises:
a process chamber;
a showerhead being provided in the process chamber and facing a workpiece;
a gas inlet for supplying a gas, which is used for forming a nitride film on the surface of the workpiece, to the showerhead, the gas inlet being formed in a rear face of the showerhead,
plasma for forming the film on the workpiece is generated between the showerhead and the workpiece by applying RF waves therebetween,
the showerhead comprises: a shower plate being made of a metal; and a porous plate being disposed to contact a rear face of the shower plate, and
a plurality of gas diffusion holes are formed in a plate section of the shower plate, which faces the workpiece, and penetrate the plate section in the thickness direction, and

the porous plate covers all of the gas diffusion holes.

Another CVD apparatus comprises:
a process chamber;
a showerhead being provided in the process chamber and facing a workpiece;
a gas inlet for supplying a gas, which is used for forming a nitride film on the surface of the workpiece, to the showerhead, the gas inlet being formed in a rear face of the showerhead,
plasma for forming the film on the workpiece is generated between the showerhead and the workpiece by applying RF waves therebetween,
the showerhead comprises a main body part being made of a metallic porous material, and
a plurality of gas diffusion grooves are formed in a plate section of the main body part, which faces the workpiece. With this structure, gasses, which are hard to be ionized, can be efficiently dissociated, so that film-forming efficiency of the CVD apparatus can be improved.

The showerhead of the present invention is constituted by the shower plate having the gas diffusion holes and the porous plate, or by the porous main body part having the gas diffusion grooves, so ionization efficiency of the showerhead can be substantially increased. By supplying the gas through the porous member, the gas can be uniformly supplied. Therefore, even if gas species, which are hard to be ionized, are used, the showerhead is capable of highly efficiently forming the film. Further, by using the porous plate or the porous main body part, the showerhead can be easily produced, a production cost of the showerhead can be reduced, and a production time thereof can be shortened.

### BRIEF DESCRIPTION OF THE DRAWINGS

Embodiments of the present invention will now be described by way of examples and with reference to the accompanying drawings, in which:

FIG. 1 is an explanation view showing an overall CVD apparatus of the present invention;

FIG. 2 is a sectional view of a showerhead of a first embodiment of the present invention;

FIG. 3 is a bottom view of a shower plate, in which gas diffusion holes are arranged;

FIG. 4 is a bottom view of the shower plate;

FIG. 5 is a bottom view of the shower plate;

FIG. 6 is a bottom view of the shower plate;

FIG. 7A is a sectional view of a modified showerhead;

FIG. 7B is a sectional view of another modified showerhead;

FIG. 8A is a sectional view of further modified showerhead;

FIG. 8B is a sectional view of further modified showerhead;

FIG. 9 is a sectional view of a showerhead of a second embodiment;

FIG. 10A is a plain view of the showerhead, in which gas diffusion holes are arranged;

FIG. 10B is a partial enlarged view of the showerhead shown in FIG. 10A;

FIG. 11A is a sectional view of a showerhead of a third embodiment;

FIG. 11B is a plan view of the showerhead of the third embodiment; and

FIG. 12 is an explanation view of the CVD apparatus to which the showerhead shown in FIGS. 11A and 11B is attached.

### DETAILED DESCRIPTION OF THE EMBODIMENTS

Preferred embodiments of the present invention will now be described in detail with reference to the accompanying drawings.

### (CVD Apparatus)

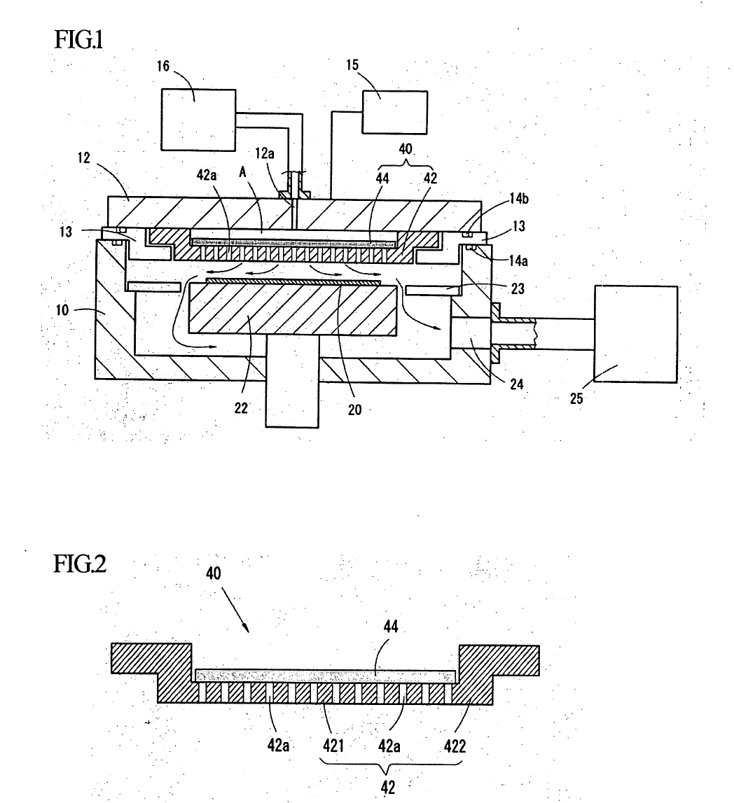

FIG. 1 is an explanation view showing an overall CVD apparatus relating to the present invention. The CVD apparatus has a process chamber 10, in which a film is formed on a surface of a workpiece 20. In the chamber 10, a showerhead 40 is disposed to face the workpiece 20, and plasma is generated therein so as to form the film on the surface of the workpiece 20.

A plate-shaped electrode 12 for applying RF waves is attached to an upper part of the chamber 10. The electrode 12 and the chamber 10 are electrically insulated by an insulation member 13. O-rings 14a and 14b are respectively provided to a contact part between the insulation member 13 and the chamber 10 and a contact part between the insulation member 13 and the electrode 12. The electrode 12 is attached to the chamber 10 and air-tightly sealed.

The electrode 12 is connected to an RF generator 15 having a matching circuit. The RF generator 15 applies prescribed RF waves to the electrode 12 for forming a film.

A gas inlet 12a is formed in the electrode 12 so as to supply a process gas for forming the film. A tube for supplying the gas to the electrode 12 is connected to a gas source 16 and the gas inlet 12a. The tube is electrically insulated.

A showerhead 40 is fixed to a bottom face of the electrode 12. The gas inlet 12a is located at the center of the showerhead 40.

The showerhead 40 comprises: a shower plate 42 having a plate section, which is formed like a flat plate and in which a plurality of gas diffusion holes 42a penetrate in the thickness direction; and a porous plate 44 provided on an upper face of the shower plate 42.

The porous plate 44 is formed into a flat plate and made of a porous ceramic or a porous metal. The porous plate 44 entirely covers the upper face of the plate section of the shower plate 42 so as to cover all of the gas diffusion holes 42a of the shower plate 42.

The showerhead 40 is attached to an inner face of the electrode 12, and an upper face of the porous plate 44 is slightly separated from an inner face of the chamber 10. A space A enclosed by the showerhead 40 and the inner face of the chamber 10 acts as a gas introduction space for introducing the gas for forming the film to the showerhead 40.

The workpiece 20 is supported on a base 22 facing the showerhead 40. A shielding plate 23 encloses the base 22 but is separated from an outer side face of the base 22. A discharge port 24 is opened in a lower side part of the chamber 10 so as to vacuum-discharge air therefrom. A vacuum pump 25 is connected to the discharge port 24.

### Showerhead of First Embodiment

The most characteristic point of the CVD apparatus is the showerhead 40 facing the workpiece 20.

FIG. 2 is an enlarged sectional view of the showerhead 40. The shower plate 42 of the showerhead 40 comprises: a plate section 421, which is formed into a flat plate and disposed to face the workpiece 20; and a flange section 422 extended from an outer edge of the plate section 421. The flange section 422 is used for attaching the showerhead 40 to the electrode 12. The shower plate 42 is made of an electric conductive material, e.g., metal.

As described above, a plurality of the gas diffusion holes 42a penetrate the plate section 421 in the thickness direction. Ratio of the width W of the gas diffusion hole 42a to the depth H thereof is 1:1-1:10. By making the depth H equal to or greater than the width W, ionizing the gas in the gas diffusion layer 42a can be accelerated and film-forming efficiency can be improved. The depth H and the width W of the gas diffusion holes 42a and distances between the gas diffusion holes 42a may be optionally designed. For example, the width W is 1.27 mm; the depth H is 3.8 mm; and the distances between the gas diffusion holes 42a are 3.8 mm. The values are optimum when process pressure is about 1 Torr. Preferably, the width W is made narrower and the depth H is made shallower when the process pressure is higher; the width W is made wider and the depth H is made deeper when the process pressure is lower.

In the present embodiment, the gas diffusion holes 42a are straight through-holes, whose inner faces are perpendicular to a surface of the plate section 421. In another case, the gas diffusion holes 42a may be female-tapered holes, each of whose diameter is gradually increased toward the lower end and whose inner faces are inclined about 5 degrees with respect to the vertical line.

### (Shower Plate)

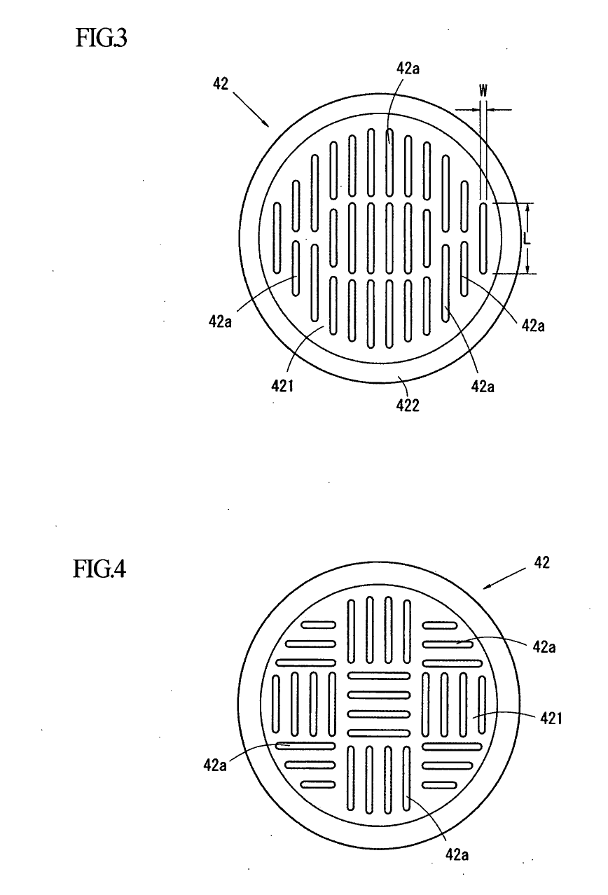

FIG. 3 is a bottom view of the shower plate 42. The gas diffusion holes 42 are straight elongate holes in plan view and arranged in parallel in the plate section 421 of the shower plate 42. Each of the gas diffusion holes 42a is a narrow elongate hole whose longitudinal ends are closed. Ratio of the width W of the gas diffusion hole 42a to the length L thereof is 1:2-1:20. By the elongate gas diffusion holes 42a, the gas, which has been supplied from the rear side of the showerhead 40 into the gas diffusion holes 42a, collides with the inner faces of the gas diffusion holes 42a. Therefore, the gas is scattered and reflected, so that the gas can be easily ionized.

The gas diffusion holes 42a may be optionally arranged in the plate section 421. Examples of arrangement of the gas diffusion holes 42a are shown in FIGS. 4-6. In FIG. 4, groups of the gas diffusion holes 42a, which are arranged in the longitudinal direction, and groups of the gas diffusion holes 42a, which are arranged in the transverse direction, are combined in the shower plate 42. Groups of the gas diffusion holes 42a are perpendicularly arranged, but they may be obliquely arranged.

In FIG. 5, the gas diffusion holes 42a are formed into circular arcs and coaxially arranged with respect to the center of the plate section 421.

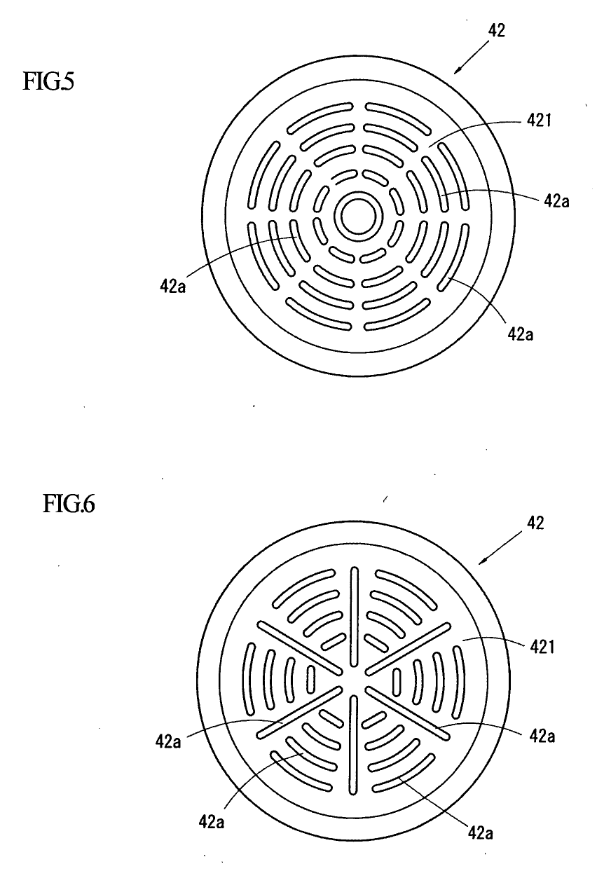

In FIG. 6, the coaxial gas diffusion holes 42a formed into circular arcs and the linear gas diffusion holes 42a radially extended from the center of the plate section 421 are combined.

Since the gas diffusion holes 42a formed in the plate section 421 of the shower plate 42 are elongate holes, dissociation of the gas can be accelerated and gas ionization efficiency can be increased. The gas ionization efficiency can be improved by combining the porous plate 44 and the shower plate 42. The gas diffusion holes 42a may be formed into not only the elongate holes but also circular holes and polygonal holes. However, in comparison with the elongate holes, the gas ionization efficiency of the circular holes or the polygonal holes is reduced to about 40%.

The shapes of the gas diffusion holes 42a and the arrangement thereof in the shower plate 42 are optionally designed according to the size and shape of the workpiece 20 and a distance between the workpiece 20 and the showerhead 40.

### (Porous Plate)

The porous plate 44 of the showerhead 40 supplies the process gas, which has been fed to the rear side of the showerhead 40, to the gas diffusion holes 42a of the shower plate 42. The porous plate 44 is made of a porous ceramic or a porous metal. The porous plate 44 is a flat plate capable of covering the entire upper face of the shower plate 42. The gas introduced from the gas inlet 12a is supplied to the gas diffusion holes 42a through the porous plate 44. With this action, the gas can be uniformly supplied into the gas diffusion holes 42a.

For example, the porous plate 44 may be made of a ceramic material, e.g., Al203, Y20, Si3N4. Pore diameters of the porous ceramic material are 0.5-100 μm, preferably 10-50 μm.

In case of using the porous plate 44 made of the porous metal, the porous plate 44 is produced by sintering Al, stainless steel, etc. Pore diameters of the porous metal are 0.5-100 μm.

The porous plate 44 supplies the gas, which has been introduced to the rear side of the showerhead 40 from the gas inlet 12a, into the gas diffusion holes 42a. The gas inlet 12a is opened at the center of the rear face of the showerhead 40. With this structure, gas density in the gas introduction space of the showerhead 40 is increased in the center part; the gas density is reduced in a peripheral part. Namely, the gas density in the gas introduction space is fluctuated. By the gas-density fluctuation, it is difficult to uniformly form the film on the surface of the workpiece 20.

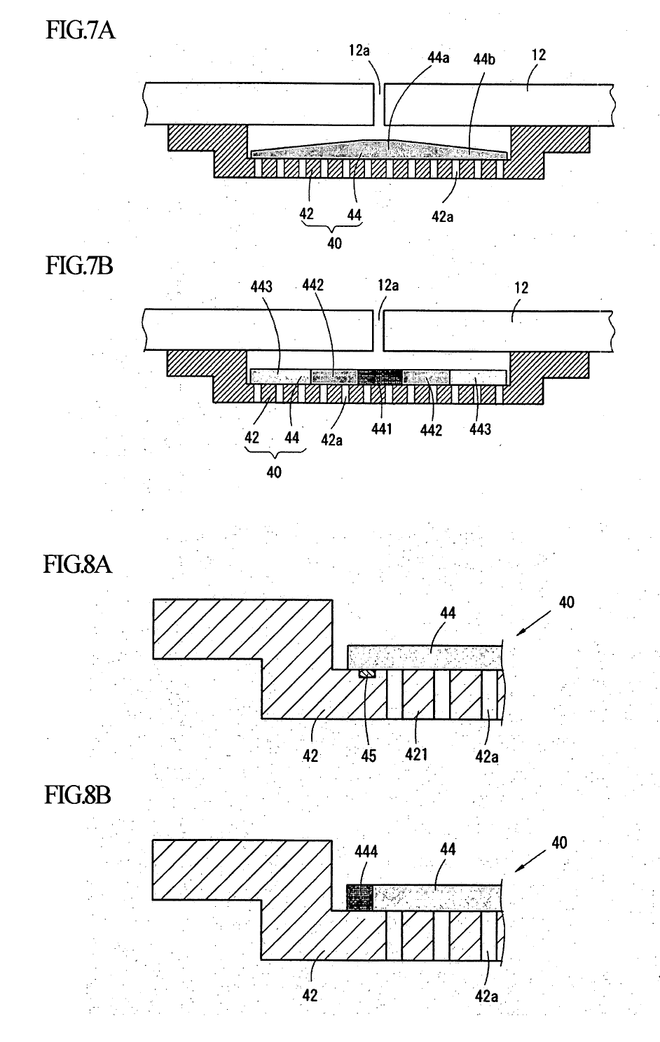

FIGS. 7A and 7B show the porous plates 44 capable of restraining the gas-density fluctuation, which is caused by the arrangement of the gas diffusion holes 42a.

In FIG. 7A, a center part of the porous plate 44 is thicker than other parts. With this structure, gas permeability in the center part can be lower than that in a perimeter part, so that the gas-density fluctuation can be restrained. The center part of the porous plate 44 is a thicker section 44a; the part on the outer side of the thick section 44a is a thin section 44b, whose thickness is gradually reduced toward an outer end. The gas permeability is reduced by thickening the porous plate 44. Therefore, the gas can be uniformly supplied to the gas diffusion holes 42a by adjusting the thickness of the porous plate 44 on the basis of the gas-density fluctuation.

In FIG. 7B, the amount of the gas supplied to the gas diffusion holes 42a is adjusted by changing density of the porous plate 44 in a planar area. Porous degree of the porous plate 44 and distribution of material density can be controlled by adjusting a grain size of a material to be sintered and sintering conditions. Thus, the density of the center part of the porous plate 44 is higher than the perimeter part thereof, so that the gas permeability of the center part of the porous plate 44, in which the gas density is high, is restrained. Therefore, the amount of gas permeation through the gas diffusion holes 42a can be uniform across the entire porous plate 44. In FIG. 7B, the density of the porous plate 44 is made highest in a center part 441 and reduced stepwise toward perimeter parts 442 and 443. Further, the density of the porous plate 44 may be gradually reduced from the center part to an outer end.

In case of attaching the porous plate 44 to the shower plate 42 to uniformly supplying the gas to the gas diffusion holes 42a, there is a problem of sealing the perimeter section of the porous plate 44 and the plate section 421 of the shower plate 42. In the vicinity of the perimeter section of the porous plate 44, the gas moves toward a lower face of the porous plate 44, so the gas cannot be uniformly supplied.

Means for solving this problem is shown in FIG. 8A. In the upper face of the plate section 421 of the shower plate 42, an O-ring 45 having heat resistance and chemical resistance is attached to the perimeter section of the porous plate 44, which surrounds the gas diffusion hole area in which the gas diffusion holes 42a are formed. Therefore, a space between the porous plate 44 and the shower plate 42 is sealed when the porous plate 44 is attached to the shower plate 42.

Another means is shown in FIG. 8B. The perimeter section 444 of the porous plate 44, which has a prescribed width and surrounds the gas diffusion hole area, is a high density section which is not gas-permeable. The perimeter section 444 is sintered with high density, so that the gas cannot invade into the porous plate 44. A contact face of the perimeter section 444 of the porous plate 44 prevents the gas from invading into the space between the porous plate 44 and the shower plate 42.

A porous sintered ceramic or metal is suitably used as the material of the porous plate 44, but the material is not limited to them. For example, other porous materials, e.g., organic porous film, may be used as the material of the porous plate 44. In case of using, for example, the porous film which cannot be attached by its own weight, the film is stretched and attached to a rear face of the plate section 421 of the shower plate 42. In the present invention, the porous film is also considered as the porous plate.

### Showerhead of Second Embodiment

In the showerhead of a second embodiment, a metal plate 50 is used instead of the porous plate 44.

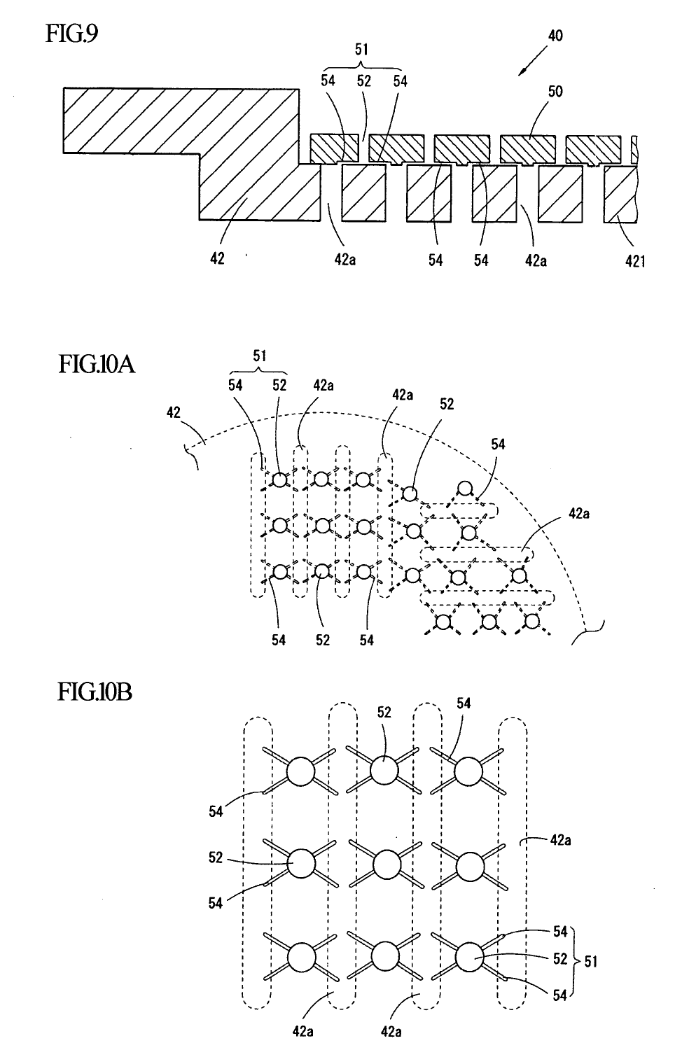

The showerhead 40 having the metal plate 50 is shown in FIGS. 9, 10A and 10B. FIG. 9 is a sectional view of the showerhead 40. In the present embodiment, the metal plate 50 having gas holes 51 is set on the plate section 421 of the shower plate 42, which has the gas diffusion holes 42a as well as the first embodiment.

Each of the gas holes 51 is constituted by: a vertical hole 52 penetrating through the metal plate 50 in the thickness direction; and communication grooves 54 being formed in a lower surface of the metal plate 50 so as to communicate with the gas diffusion holes 42a.

The vertical holes 52 are arranged so as not to correspond to the gas diffusion holes 42a. In another words, each of the vertical holes 52 is located between the adjacent gas diffusion holes 42a and covered with the plate section 421 of the shower plate 42.

On the other hand, the communication grooves 54 are extended from the vertical holes 52 until reaching the gas diffusion holes 42a, so that the vertical holes 52 can be communicated with the gas diffusion holes 42a.

FIG. 10A is a plan view showing the planar arrangement of the gas diffusion holes 42a of the shower plate 42 and the gas holes 51 of the metal plate 50. FIG. 10B is an enlarged view showing the arrangement of the gas holes 51.

The vertical hole 52 of each gas hole 51 is located at a midpoint between the adjacent gas diffusion holes 42a, and a plurality of the communication grooves 54 are extended from the vertical hole 52 until reaching the adjacent gas diffusion holes 42a. A plurality of the communication grooves 54 are communicated with each of the gas diffusion holes 42a. Therefore, the process gas is supplied to the gas diffusion holes 42a via the vertical holes 52 and the communication grooves 54.

The gas introduced from the gas inlet 12a must be uniformly supplied to the gas diffusion holes 42a of the showerhead 40. In the present embodiment, the communication grooves 54 of the gas holes 51 are made narrow so as to uniformly supply the gas to the gas diffusion holes 42a of the shower plate 42.

On the other hand, the vertical holes 52 formed in the metal plate 50 need not be made narrow because the gas flow is limited by the communication grooves 54. The vertical holes 52 may be relatively wide because the gas is supplied to the gas diffusion holes 42a via the communication grooves 54. Unlike the conventional showerhead, a large number of small gas diffusion holes need not be formed, so the metal plate 50 can be easily produced.

In the showerhead 40 of the present embodiment too, the process gas, which has been supplied into the gas diffusion holes 42a via the gas holes 51, collides with the inner faces of the gas diffusion holes 42a. Therefore, the gas is scattered and reflected, so that the gas can be easily ionized and the film can be efficiently formed.

### Showerhead of Third Embodiment

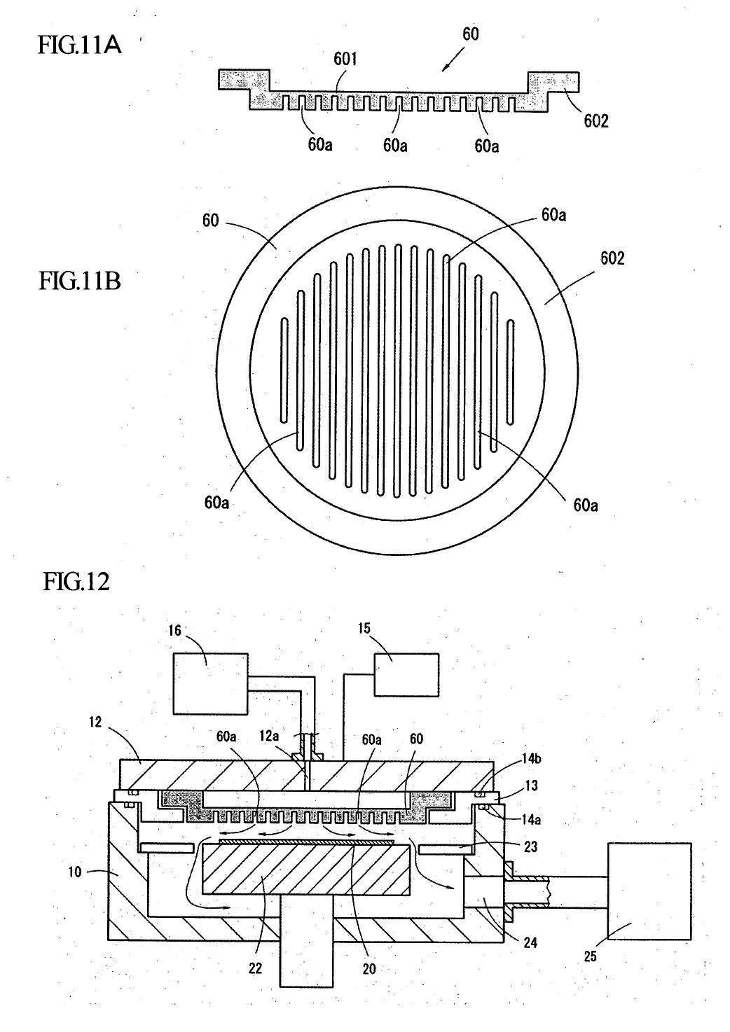

The showerhead of the third embodiment is shown in FIGS. 11A and 11B. A showerhead 60 of the present embodiment is characterized by a porous main body made of a sintered metal.

FIG. 11A is a sectional view of the showerhead 60. The showerhead 60 comprises: a plate section 601; and a flange section 602, which is extended from an outer edge of the plate section 601. The flange section 602 is attached to the electrode 12, and a gas introduction space is formed on the rear side of the plate section 601.

A plurality of gas diffusion grooves 60a are formed in a surface of the plate section 601, which faces the workpiece 20. The gas diffusion holes 42a of the shower plate 42 are through-holes penetrating the plate section 421 in the thickness direction; the gas diffusion grooves 60a are grooves whose upper parts are closed. In the above described showerhead 40, the shower plate 42 and the porous plate 44 are combined so as to close the upper parts of the gas diffusion holes 42a like grooves. On the other hand, in the present embodiment, the gas diffusion grooves 60a are formed in the main body part of the showerhead 60.

Planar shapes of the gas diffusion grooves 60a, which are formed in the plate section 601 of the showerhead 60, are not limited as well as those of the gas diffusion holes 42a of the above described showerhead 40. FIG. 11B is a plan view showing the planar arrangement of the gas diffusion grooves 60a of the showerhead 60, wherein the gas diffusion grooves 60a are linear grooves. The gas diffusion grooves 60a are elongate grooves as well as the elongate gas diffusion holes 42a, so that ionization of the process gas in the gas diffusion grooves 60a can be accelerated and film-forming efficiency can be improved.

FIG. 12 shows a CVD apparatus, in which the showerhead 60 shown in FIGS. 11A and 11B is attached. The showerhead 60 is attached to the inner face of the electrode 12. The structure of the CVD apparatus is the same as that shown in FIG. 1. The RF generator 15 is electrically connected to the electrode 12, and RF waves are applied to the showerhead 60, which is made of an electric conductive material, so as to generate plasma for forming the film.

In the CVD apparatus, the process gas for forming the film, which has been supplied to the rear side of the showerhead 60 via the gas inlet 12a, permeates the porous plate section 601 of the showerhead 60 until reaching the gas diffusion grooves 60a. Thicknesses of ceiling sections of the gas diffusion grooves 60a are thinner than a thickness of the plate section 601, so the gas permeates the ceiling sections and reaches the gas diffusion grooves 60a. Then, the gas is dissociated in the gas diffusion grooves 60a.

In case of using the main body part of the showerhead 60 made of a porous conductive material, e.g., porous metal, the main body part can be formed by compression-molding the material with a molding die and sintering the molded material. Unlike the conventional showerhead in which a large number of small holes are bored by drilling, the showerhead 60 can be highly easily produced. Further, shapes of the gas diffusion grooves 60a can be optionally selected by changing the molding die.

In the CVD apparatus, a sectional shape of the plate section 601 may be formed into a mountain shape as well as the porous plate 44 shown in FIG. 7A, and density of the plate section 601 may be partially varied as well as the porous plate 44 shown in FIG. 7B. With these structures, gas-density variance in the gas diffusion grooves 60a, which is caused by gas-density fluctuation in the gas introduction space of the showerhead 60, can be restrained.

### (Operation of CVD Apparatus)

Next, the process of forming the film on the surface of the workpiece 20 with the above described CVD apparatus will be explained.

As shown in FIG. 1, the workpiece 20 is set on the base 22 so as to face the showerhead 40. The base 22 heats the workpiece 20 until reaching reaction temperature. In case of forming a nitride film, e.g., silicon nitride film, the reaction temperature is about 400° C.

The distance between the showerhead 40 and the workpiece 20 is an important factor to uniformly forming the film on the surface of the workpiece 20. Further, the size and arrangement of the gas diffusion holes 42a of the showerhead 40 are also important factors. Therefore, the distance between the showerhead 40 and the workpiece 20 is designed according to other factors, e.g., gas diffusion holes. In case of forming the silicon nitride film, for example, the distance between the showerhead 40 and the workpiece 20 is 6-35 mm.

Firstly, the process gas for forming the film is introduced into the gas introduction space, which is formed on the rear side of the showerhead 40, via the gas inlet 12a. The gas supplied on the rear side of the showerhead 40 permeates the porous plate 44 and reaches the gas diffusion holes 42a. On the other hand, in the showerhead 40 having the metal plate 50, the gas is supplied to the gas diffusion holes 42a via the gas holes 51 of the metal plate 50. Further, in the showerhead 60 having the porous main body part, the gas permeates the plate section 601 and reaches the gas diffusion grooves 60a.

The RF generator 15 applies RF waves to the showerhead 40 or 60 so as to generate plasma in a space between the workpiece 20 and the showerhead 40 or 60, so that the film is formed on the surface of the workpiece 20. There are several methods for applying RF waves. Namely, RF waves may be applied to the showerhead 40 or 60 only, or RF waves may be applied to the workpiece 20 (the base 22) only. Further, RF waves may be applied to the both of the showerhead 40 or 60 and the workpiece 20. In this case, for example, RF waves of higher frequency (about 1.3 MHz) may be applied to the showerhead 40 or 60 so as to efficiently dissociate the gas; RF waves of lower frequency (about 500 KHz) may be applied to the workpiece 20 so as to efficiently bombard ions. The CVD apparatus of the present invention may employ any of the methods.

By supplying the process gas to the gas diffusion holes 42a or the gas diffusion grooves 60a, the gas can stably charge and is easily dissociated in the groove-shaped spaces. Therefore, even if the gas which is hard to be ionized, e.g., silicon nitride, is used, the film can be efficiently formed.

For example, in case of forming the silicon nitride film, which will be used as a protection film or an insulation film of a semiconductor device, SiH4⁺NH3, SiH4+N2 and SiH4++NH3+N2 may be used as the gas species. To efficiently ionize the process gas, a preferable frequency of the RF waves is 2-100 MHz, more preferably 13 MHz. A preferable gas pressure is 0.5-4 Torr, more preferably 1 Torr.

In case of using the gas of SiH4+N2, N2 must be dissociated, but little N2 is dissociated by the conventional showerhead in which the small gas holes are bored. On the other hand, the showerhead of the present invention has the groove-shaped gas diffusion spaces, which are formed by the gas diffusion holes 42a and the porous plate 44 or the gas diffusion grooves 60a formed in the showerhead itself, so that N2 can be efficiently ionized in the gas diffusion holes or grooves.

In case of using the gas of SiH4+NH3, according to an experiment, the film-forming efficiency of the CVD apparatus was 2.5 times greater than that of the conventional CVD apparatus. By permeating the gas through the porous member, the gas can be uniformly supplied so that the film can be stably and uniformly formed.

The workpiece 20 used in the CVD apparatus of the present invention may be a semiconductor wafer, a solar battery panel, an LCD panel, etc. The porous plate 44, which is made of a ceramic or a sintered metal, and the showerhead 60 having the porous main body part can be highly cleaned, so they can be suitably used for the film-forming process.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A showerhead for a CVD apparatus,
comprising:
a shower plate being made of a metal; and
a porous plate contacting a rear face of said shower plate,
wherein a plurality of gas diffusion holes are formed in a plate section of said shower plate, which faces a workpiece, and penetrate the plate section in the thickness direction, and
said porous plate covers all of the gas diffusion holes.

2. The showerhead according to claim 1, wherein the gas diffusion holes are elongate holes.

3. The showerhead according to claim 1,
wherein a thickness of said porous plate is thicker in a high gas-density area of a gas introduction space, which is formed on the rear side of said shower head, and
the amount of gas permeation through the gas diffusion holes is uniform across said entire showerhead.

4. The showerhead according to claim 1,
wherein density of said porous plate is higher in a high gas-density area of a gas introduction space, which is formed on the rear side of said shower head, and
the amount of gas permeation through the gas diffusion holes is uniform across said entire showerhead.

5. The showerhead according to one of claim 1,
wherein said porous plate has a perimeter section, which surrounds a gas diffusion hole area, and
the perimeter section is not gas-permeable.

6. The showerhead according to one of claim 1,
wherein a metal plate is installed instead of said porous plate,
said metal plate has:
vertical holes penetrating through said metal plate in the thickness direction; and
communicating grooves being formed in a surface of said metal plate, which contacts the plate section of said shower plate, said communicating grooves mutually communicating the gas diffusion holes.

7. A showerhead for a CVD apparatus,
comprising a main body part being made of a metallic porous material,
wherein a plurality of gas diffusion grooves are formed in a plate section of said main body part, which faces a workpiece.

8. The showerhead according to claim 7,
wherein said gas diffusion grooves are elongated grooves in plan view.

9. The showerhead according to claim 8,
wherein a thickness of the main body part is thicker in a high gas-density area of a gas introduction space, which is formed on the rear side of said shower head, and
the amount of gas permeation through the gas diffusion grooves is uniform across said entire main body part.

10. The showerhead according to claim 8,
wherein density of said main body part is higher in a high gas-density area of a gas introduction space, which is formed on the rear side of said shower head, and
the amount of gas permeation through the gas diffusion grooves is uniform across said entire main body part.

11. A CVD apparatus,
comprising:
a process chamber;
a showerhead being provided in said process chamber and facing a workpiece;
a gas inlet for supplying a gas, which is used for forming a nitride film on the surface of the workpiece, to said showerhead, said gas inlet being formed in a rear face of said showerhead,
wherein plasma for forming the film on the workpiece is generated between said showerhead and the workpiece by applying RF waves therebetween,
said showerhead comprises: a shower plate being made of a metal; and a porous plate being disposed to contact a rear face of said shower plate, and
a plurality of gas diffusion holes are formed in a plate section of said shower plate, which faces the workpiece, and penetrate the plate section in the thickness direction, and
said porous plate covers all of the gas diffusion holes.

12. A CVD apparatus,
comprising:
a process chamber;
a showerhead being provided in said process chamber and facing a workpiece;
a gas inlet for supplying a gas, which is used for forming a nitride film on the surface of the workpiece, to said showerhead, said gas inlet being formed in a rear face of said showerhead,
wherein plasma for forming the film on the workpiece is generated between said showerhead and the workpiece by applying RF waves therebetween,
said showerhead comprises a main body part being made of a metallic porous material, and
a plurality of gas diffusion grooves are formed in a plate section of said main body part, which faces the workpiece.
